(19) United States
(12) Patent Application Publication
(10) Pub. No.: US 2006/0050493 A1
(43) Pub. Date: Mar. 9, 2006

(54) LSI package with interface module, transmission line package, and ribbon optical transmission line

(76) Inventors: Hiroshi Hamasaki, Hiratsuka-shi (JP); Hideto Furuyama, Yokohama-shi (JP); Hideo Numata, Yokohama-shi (JP); Chiaki Takubo, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/205,142

(22) Filed: Aug. 17, 2005

(30) Foreign Application Priority Data
Aug. 17, 2004 (JP) P2004-237722
Aug. 17, 2004 (JP) P2004-237723

(51) Int. Cl. H05K 7/10

(52) U.S. Cl. 361/767; 385/14; 361/785; 361/803

(57) ABSTRACT

According to an aspect of the present invention, there is provided an LSI package with an interface module including: an interposer, on which a signal processing LSI is mounted, having a mounting board connecting electrical terminal; and an interface module having a transmission line to wire a high-speed signal to the exterior and a socket connecting electrical terminal corresponding to a mounting board connecting socket, in which the interposer and the interface module have at least either loop electrodes or plate electrodes, respectively, and the interposer and the interface module are electrically connected by inductive coupling, electrostatic coupling, or combined coupling of these two couplings by at least either the loop electrodes or the plate electrodes.

### CROSS-REFERENCE TO RELATED APPLICATIONS

This application is based upon and claims the benefit of priority from the prior Japanese Patent Applications No. 2004-237722 and 2004-237723, filed on Aug. 17, 2004, respectively; the entire contents of which are incorporated herein by reference.

### BACKGROUND OF THE INVENTION

1. Field of the Invention

The present invention relates to an LSI package with an interface module including an interface module to wire a high-speed signal to an exterior, a transmission line package applied to high-speed LSI mounting, and a ribbon optical transmission line.

2. Description of the Related Art

In recent years, the clock frequency of an LSI has been getting increasingly higher and a CPU for a personal computer that is operated with a frequency of GHz or higher has been put into practical use. However, the pace of improvement in the throughput of an interface between LSIs is moderate, compared with increase in clock frequency, which constitutes a bottleneck in the performance of the personal computer. Hence, research and development on the improvement in the throughput of the interface are actively performed.

For improving the throughput of the interface, it is necessary to increase the signal frequency per terminal and to increase the number of terminals. However, there is a limit to the increase in the number of terminals because the increase in the number of terminals results in the enlargement of the areas of an LSI and a package to lengthen the internal wiring length, which hinders a high-frequency operation, and therefore the increase in the frequency per terminal becomes a large problem. On the other hand, the increase in the frequency per terminal results in larger attenuation of an electrical signal and a larger influence of reflection due to impedance mismatch, which imposes a limit on the line length. Therefore, it is necessary to use a transmission line with the smallest possible impedance mismatch and attenuation amount, as a high-speed signal transmission line. The accurate formation of the transmission line on a mounting board causes not only cost increase but also increases in dielectric loss and conductor loss due to a skin effect with an increase in speed, which makes transmission over a sufficient distance difficult. Accordingly, a method of wiring a high-speed signal wire only on an interposer without wiring it on a mounting board, performing photoelectric conversion by an optical element mounted on the interposer, and performing transmission by light is studied. Among its examples are Japanese Patent Application Laid-open No. 2004-31455 and Module with Built-in Optical I/O (1) Module Structure and Design Manual (Ichiro Hatakeyama and eight others, the Institute of Electronics, Information and Communication Engineers, Electronics Society Conference, 2003, C-3-123, p. 256).

In the case of Japanese Patent Laid-open Application No. 2004-31455, the optical element is directly bare-chip mounted on an interposer board and optically coupled to an optical waveguide when the interposer board is mounted on the mounting board, so that it is difficult to maintain optical accuracy because of the difference in thermal expansion coefficient between the mounting board and the interposer. Further, since it is difficult to ensure reliability of the bare optical element, it is necessary to adopt a method of embedding an optical element portion with a transparent resin or the like, for example, at a wavelength used for signal transmission, but there is a problem that this method needs a work on the mounting board, has many restrictions in terms of manufacturing, and costs a lot. There is another problem that an extra work of attaching the optical waveguide to the mounting board is necessary, which complicates the mounting process, resulting in cost increase. There is still another problem that when the optical element breaks down, an expensive signal processing LSI has to be also renewed together with the optical element.

The structure shown in Module with Built-in Optical I/O (1) Module Structure and Design Manual adopts a method of directly mounting an optical component on an LSI package. Therefore, it is necessary that the LSI package is reflow mounted on the mounting board while the optical component is mounted thereon or the optical component is mounted after the LSI package is reflow mounted on the mounting board, whereby in this structure, the optical component and an assembling material (such as an adhesive) which are easily affected by heat and the reflow mounting at the time of board mounting interfere with each other. Moreover, mutual interference among soldering of the LSI, soldering of the optical interface module, and, in some cases, soldering of the interposer occurs, which poses a problem in terms of mounting such as the occurrence of restrictions on the mounting procedure. Further, in order to hold the optical connector in a proper position, a pressing force holding mechanism is additionally required. Because of this reason and so on, the use of the connector for the optical connection tends to enlarge the mechanism. Namely, an accuracy as high as several micro-meters to 10 micro-meters is required as the mounting accuracy of the optical connector, and hence the holding mechanism of the connector is difficult to downsize, and tends to be upsized. Therefore, there are a problem of cost increase caused by the complication of the structure, for example, by the formation of a recessed space in a heat sink attached on an upper portion of the LSI, and a problem that it becomes difficult to attach a heat sink for heat release of the optical interface module.

In general, power consumption per terminal tends to become larger with an increase in the frequency of a signal. For example, in recent years, the power consumption of some LSI amounts to 70 W to 80 W in a CPU used in a personal computer or the like. A structure adopted under the circumstances is such that a heat spreader and a gigantic heat sink are provided on the signal processing LSI so as to secure a large heat release area, and forced air cooling is performed by using a fan or the like. On the other hand, the wiring length between the signal processing LSI and the interface module has to be as short as possible as described above. Therefore, in the case where the heat sink for the signal processing LSI is installed, there is no allowance in the space for providing another heat sink for the interface module.

Also in this case, there is a problem that since the interface module is soldered, the expensive signal processing LSI has to be also renewed together when the interface module breaks down.

Meanwhile, optical wiring has little frequency dependence which is lost at a frequency of direct current to 100 GHz or higher, and has no electromagnetic interference of wiring paths and no fluctuating noise at ground potential, so that the wiring at several tens of gigabits per second can be easily realized. As this kind of optical wiring between signal processing LSIs, for example, Optical-interconnection as IP macro of a CMOS Library (Takashi Yosikawa, IEEE HOT9, Interconnects. Symposium on High Performance Interconnects, 2001, p.p. 31-5) and so on are known, and a structure in which an interface module to wire a high-speed signal to the exterior is directly mounted on an interposer on which a signal processing LSI is mounted, is proposed.

An example of board mounting of the LSI package according to this prior art, that is, a transmission line package will be described in FIG. 33. In FIG. 33, numeral 1001 denotes a mounting board, numeral 1002 denotes an LSI package substrate, numeral 1003 denotes an LSI chip, numeral 1004 denotes a solder ball, numeral 1005 denotes an optical interface, and numeral 1006 denotes an optical fiber, and two LSI packages are mounted on the right and left side, and the transmission line is aerially wired between these packages.

However, such an LSI package as shown in the conventional example has a problem that it is difficult to control the line length of the transmission line to be aerially wired when the LSI package is mounted on the mounting board. Namely, the length of the transmission line is determined according to the layout design of LSI packages, and in consideration of allowances for attachment to connectors and the LSI packages, the transmission line is cut to a predetermined length and attached, but at this time, it is difficult to reduce a fabrication error to zero, and it is common that a small length error occurs. Moreover, depending on the difference in thermal expansion coefficient between the mounting board and transmission line, a relative error between the LSI packages, that is, between the wiring length viewed from the board and the transmission line length occurs according to ambient temperature change. Hence, the transmission line in such a package needs to be formed longer than the predetermined length, but a deflection of the transmission line caused by its extra length is not properly processed.

In such a transmission line package, the above-described fabrication error of the transmission line is absolutely inevitable. When the transmission line is shorter than the wiring length, the LSI package is pulled by the transmission line, which causes troubles such as poor mounting of the LSI package, breakage of the optical interface or the transmission line, and so on. Therefore, the transmission line longer than the predetermined wiring length is used, and consequently, the deflection of the transmission line such as shown in FIG. 33 occurs because of its extra length.

When the deflection caused by this extra length becomes several tens of millimeters, in some cases, the aerially wired transmission line is caught by another component of the mounting board or sympathetically vibrates by cooling air from a cooling fan to thereby be damaged at its base portion.

Accordingly, since the deflection of the transmission line caused by the extra length is not properly processed, stress caused by the deflection of the transmission line is applied to the optical interface and the LSI package. As a result, a problem such that in order to cope with the stress, a pressing mechanism is upsized, tends to occur.

### BRIEF SUMMARY OF THE INVENTION

According to an aspect of the present invention, there is provided an LSI package with an interface module comprising: an interposer, on which a signal processing LSI is mounted, having a mounting board connection electrical terminal; and an interface module having a transmission line to wire a high-speed signal to an exterior, wherein the interposer and the interface module have at least either loop electrodes or plate electrodes, respectively, and the interposer and the interface module are electrically connected by inductive coupling, electrostatic coupling, or combined coupling of these two couplings by at least either the loop electrodes or the plate electrodes.

According to another aspect of the present invention, there is provided an LSI package with an interface module comprising: an interposer, on which a signal processing LSI is mounted, having a mounting board connection electrical terminal; an interface module having a transmission line to wire a high-speed signal to an exterior; an electrical connector mounted on at least either the interposer or the interface module; and a flexible electrical wire whose at least one end portion is connected to the electrical connector, wherein the interposer and the interface module have electrical connection terminals which are electrically connected, respectively, and the electrical connection terminals are electrically connected by the flexible electrical wire.

According to another aspect of the present invention, there is provided an LSI package with an interface module comprising: an interposer, on which a signal processing LSI is mounted, having a high-speed signal electrical terminal and a socket connection terminal pin; an interface module having a transmission line to wire a high-speed signal to an exterior, a high-speed signal electrical terminal, and a socket connection terminal pin; a high-speed signal wire electrically connecting the high-speed signal electrical terminal of the interposer and the high-speed signal electrical terminal of the interface module to each other; and a socket having jacks fittable with the socket connection terminal pin of the interposer and the socket connection terminal pin of the interface module, wherein the high-speed signal electrical terminal of the interposer and the high-speed signal electrical terminal of the interface module come into mechanical contact with the high-speed signal wire by pressing force due to deflections of the high-speed signal electrical terminals and get electrically connected to each other, and the mechanical contact is held by fitting the socket connection terminal pin of the interposer and the socket connection terminal pin of the interface module into the jacks, respectively.

According to another aspect of the present invention, there is provided an LSI package with an interface module comprising: an interposer, on which a signal processing LSI is mounted, having a mounting board connecting electrical terminal; and an interface module having an optical fiber to wire a high-speed signal to an exterior, wherein the interposer and the interface module have electrical connection terminals which are electrically connected, respectively, and the electrical connection terminals are connected by a solder having a melting point lower than a board mounting solder.

According to another aspect of the present invention, there is provided a transmission line package comprising: a mounting board; a transmission line aerially wired from a first wiring point on the mounting board to a second wiring point on the mounting board and longer than a shortest wiring length from the first wiring point to the second wiring point by a range not less than 2% nor more than 20% of the shortest wiring length; and a hook which pulls the transmission line toward the mounting board at a height equal to or lower than a straight-line wiring height from the first wiring point to the second wiring point or a fixing member which fixes the transmission line to the mounting board.

According to another aspect of the present invention, there is provided a transmission line package comprising: a mounting board; and a ribbon optical transmission line aerially wired from a first wiring point on the mounting board to a second wiring point on the mounting board, arranged in array long sideways, and having a twisted portion or a curved portion formed between the first wiring point and the second wiring point.

According to another aspect of the present invention, there is provided an LSI package with an interface module comprising: a signal processing LSI; an interposer, on which the signal processing LSI is mounted, having a mounting board connection electrical terminal; and an interface module having a ribbon optical transmission line composed of an optical waveguide body array to wire a high-speed signal to an exterior, wherein the interposer and the interface module have electrical connection terminals which are electrically connected by mechanical contact, and the ribbon optical transmission line has a twisted portion or a curved portion.

According to another aspect of the present invention, there is provided a ribbon optical transmission line which is linearly arranged in array in a direction orthogonal to an optical transmission direction, comprising a twisted portion, or a curved portion in a direction orthogonal to the direction of the array arrangement in a middle of the ribbon optical transmission line.

### BRIEF DESCRIPTION OF THE DRAWINGS

FIG. 1 is a view showing a schematic structure of an LSI package with an interface module according to a first embodiment of the present invention.

FIG. 2A and FIG. 2B are each an enlarged view of a connection portion of a high-speed signal wire according to the first embodiment of the present invention.

FIG. 3 is a view showing a mounting process of the LSI package with the interface module according to the first embodiment of the present invention.

FIG. 4 is a view showing a schematic structure of another LSI package with an interface module according to the first embodiment of the present invention.

FIG. 5 is a view showing a schematic structure of an LSI package with an interface module according to a second embodiment of the present invention.

FIG. 6 is a view showing a connecting process of an optical interface module according to the second embodiment of the present invention.

FIG. 7 shows a top view of an interposer with an FPC according to the second embodiment of the present invention.

FIG. 8 is a view showing a schematic structure of an LSI package with an interface module according to a third embodiment of the present invention.

FIG. 9 is an enlarged view of a connection portion of a high-speed signal wire according to the third embodiment of the present invention.

FIG. 10 is a view showing a connecting process of an optical interface module according to the third embodiment of the present invention.

FIG. 11 is a view showing a schematic structure of an LSI package with an interface module according to a fourth embodiment of the present invention.

FIG. 12 is an enlarged view of a connection portion of a high-speed signal wire according to the fourth embodiment of the present invention.

FIG. 13 is a view showing a connecting process of an optical interface module according to the fourth embodiment of the present invention.

FIG. 14 is a view showing a schematic structure of an LSI package with a interface module according to a fifth embodiment of the present invention.

FIG. 15 is a view showing a connecting process of an optical interface module according to the fifth embodiment of the present invention.

FIG. 16 is a schematic structural view showing a transmission line package in a sixth embodiment of the present invention.

FIG. 17 is a cross-sectional view showing a hook in the sixth embodiment of the present invention.

FIG. 18 is an explanatory view explaining a deflection of an optical fiber in the sixth embodiment of the present invention.

FIG. 19 is a graph showing calculation results of the deflection amount of the optical fiber in the sixth embodiment of the present invention.

FIG. 20A is a top view showing a schematic structure of a transmission line package in a seventh embodiment, and FIG. 20B is a cross-sectional view showing the schematic structure of the transmission line package in the seventh embodiment.

FIG. 21 is a structural view showing a transmission line package in an eighth embodiment.

FIG. 22 is a structural view showing a transmission line package in a ninth embodiment.

FIG. 23 is a structural view showing a transmission line package in a tenth embodiment.

FIG. 24 is a structural view showing a transmission line package in an eleventh embodiment.

FIG. 25 is a perspective view showing a channel holder in the eleventh embodiment.

FIG. 26 is a perspective view showing a ribbon optical fiber in an twelfth embodiment.

FIG. 27 is a perspective view showing the ribbon optical fiber in the twelfth embodiment.

FIG. 28 is a perspective view showing a ribbon optical fiber in a thirteenth embodiment.

FIG. 29 is a perspective view showing the ribbon optical fiber in the thirteenth embodiment.

FIG. 30 is a side view showing the ribbon optical fiber in the thirteenth embodiment.

FIG. 31 is a perspective view showing a ribbon optical fiber and a holding plate in a fourteenth embodiment.

FIG. 32 is a cross-sectional view showing an LSI package with an interface module in the sixth embodiment.

FIG. 33 is a structural view showing a conventional transmission line package.

### DETAILED DESCRIPTION OF THE INVENTION

Hereinafter, embodiments of the present invention will be described with reference to the drawings. In the following description of the drawings, the same or similar components are denoted by the same or similar numerals and symbols. It should be noted that the drawings are schematic and, thus, the relationship between the thickness and the planar size, the ratio in thickness between respective layers, and so on differ from the actual ones. Accordingly, the specific thickness and size should be determined in consideration of the following description. Also, it is a matter of course that the drawings include portions where the mutual size relation and the ratios differ from each other.

Moreover, the embodiments shown below illustrate devices and methods to embody the technical idea of the present invention, and the technical idea of the present invention does not limit the material, shape, structure, placement, and so on of each of components to the following ones. Various changes may be made in the technical idea of the present invention within the scope of the claims.

### First Embodiment

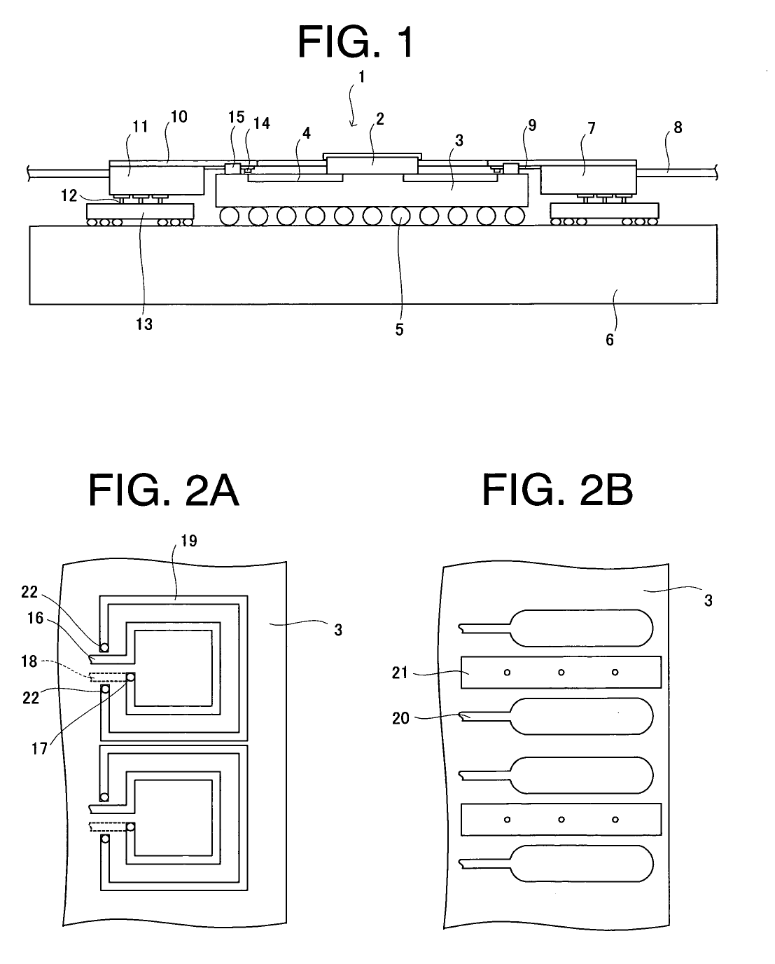

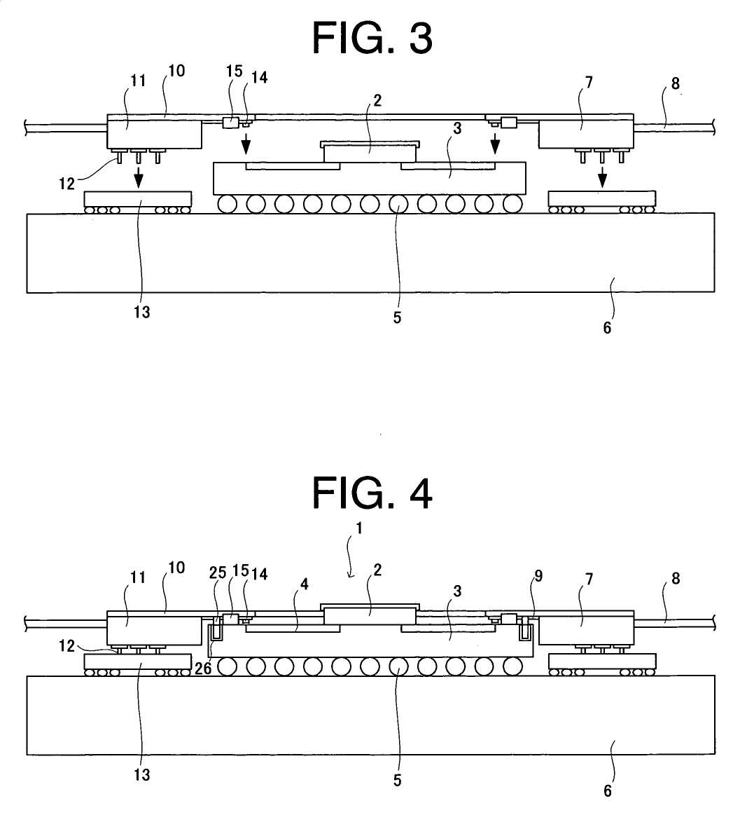

FIG. 1 is a view showing a schematic structure of an LSI package with an interface module according to a first embodiment of the present invention, FIG. 2A and FIG. 2B are enlarged views of a connection portion of a high-speed signal wire according to the first embodiment of the present invention, FIG. 3 is a view showing a mounting process of the LSI package with the interface module according to the first embodiment of the present invention, and FIG. 4 is a view showing a schematic structure of another LSI package with an interface module according to the first embodiment of the present invention.

In FIG. 1, numeral 1 denotes an LSI package with an interface module, and the LSI package with the interface module 1 includes a signal processing LSI 2. The signal processing LSI 2 is mounted on an interposer 3, and the signal processing LSI 2 and the interposer 3 are electrically connected.

A high-speed signal wire 4 is wired in the interposer 3, and the high-speed signal wire 4 is electrically connected to a signal input/output terminal (not shown) of the signal processing LSI 2. The other end of the high-speed signal wire 4 is drawn out to the Surface side of the interposer 3. Connection terminals 5 (a mounting board connection electrical terminal) for power supply, input/output of a low-speed control signal, and soon are placed on a lower surface of the interposer 3, and the connection terminals 5 and a mounting board 6 are electrically connected.

Numeral 7 denotes an optical interface module. This optical interface module 7 has an interface IC, an optical element, an optical fiber 8 (a transmission line) to wire a high-speed signal to an exterior, an optical coupling system of the optical fiber 8 and the optical element, a flexible printed circuit 9 (hereinafter described as an FPC) and so on, and it is mounted on a stiffener 10 being a supporting substrate and entirely protected by a molding resin 11 or the like.

The optical interface module 7 has two kinds of input/output portions. More specifically, one input/output portion is input/output pins 12 (a socket connection electrical terminal) which are provided on the mounting board 6 side and correspond to a later-described socket 13, and is to transmit a low-speed control signal, a power supply signal, and so on. The input/output pins 12 are connected to the socket 13 (amounting board connection socket) mounted on the mounting board 6. The other input/output portion is an electrical connection portion 14 to electrically connect the optical interface module 7 and the high-speed signal wire 4 and is to transmit a high-speed signal. The electrical connection portion 14 is placed at a predetermined distance from the high-speed signal wire 4 by a projection 15.

FIG. 2A is a view showing one example of inductive coupling. Numeral 16 denotes a loop electrode provided at a portion of the high-speed signal wire 4. The loop electrode 16 forms a loop for each terminal at a peripheral portion of the interposer 3 as shown, and has a return 18 in another layer via a through hole 17. It functions as a loop antenna by connecting the return 18 as it is to a ground or a power supply, but also can function as a traveling-wave antenna by connecting a terminal resistance to the return 18. Numeral 19 denotes a shield to prevent the influence of an external electric field and cross talk of a magnetic field, and the shield is shorted to the power supply or ground level by a through hole 22. The same structure as this one is formed in the electrical connection portion 14 and placed facing this one with an appropriate gap therebetween, so that the respective structures function as an output antenna and a receiving antenna, which realizes electrical connection without pressing by inductive coupling dominated by magnetic coupling.

FIG. 2B is a view showing one example of electrostatic coupling. Numeral 20 denotes plate electrodes provided at a portion of the high-speed signal wire 4, which, for example, form differential wire pairs as shown in FIG. 2B. Numeral 21 denotes a ground line to electrically separate each differential pair. The same structure as this one is also provided in the electrical connection portion 14 and placed facing this one with an appropriate gap therebetween, so that parallel plates are formed, which enables electrical connection by electrostatic coupling dominated by electric field coupling. Incidentally, it is needless to say that such electrical connection by electrostatic coupling results in AC coupling without resulting in DC coupling.

To mount such an LSI package 1 with the interface module on the mounting board 6, first, the interposer 3 on which the signal processing LSI 2 is mounted is electrically connected to the mounting board 6 by the connection terminals 5. At this time, preferably simultaneously with the above, the socket 13 and other mounting components are mounted on the mounting board 6. Thereafter, the loop electrode 16 or the plate electrode 20 on the interposer 3 side and the loop electrode 16 or the plate electrode 20 of the optical interface module 7 are aligned. Simultaneously with the insertion of the input/output pins 12 into the socket 13, the optical interface module 7 and the high-speed signal wire 4 are electrically connected by the electrical connection portion 14. Here, the electrical connection portion 14 has a structure of being electrically connected by inductive coupling, electrostatic coupling, or combined coupling of these two couplings, and it is not directly mechanically in touch. This structure enables electrical connection without pressing force by designing the height error in a gap direction within a design specification range. By providing the projection 15 corresponding to the gap to define the gap at this time, a connection characteristic is stabilized.

This structure makes it possible to mount the interposer 3 on the mounting board 6 through substantially the same process as that of mounting a typical BGA packaged LSI (the state in FIG. 3) and thereafter electrically connect the optical interface module 7 (the state in FIG. 1). Namely, after electrical mounting of the interposer 3 together with other components on the mounting board 6, that is, heat treatment such as reflow and laser heating, the optical interface modules 7 can be mounted, and hence a structure highly suitable for electrical mounting is achieved.

Since the optical interface modules 7 are packaged separately, reliability can be ensured, further, the optical interface module 7 has a structure that can be inspected by itself, and therefore, the deterioration of yields of the mounting board 6 caused by a defective optical element can be prevented. Since the optical interface module 7 can be mounted by electrical mounting without undergoing heat treatment, a little restriction is imposed on mounting when a pigtail method is adopted. Naturally, a high-speed signal reaches the optical interface module 7 from the interposer 3 via the electrical connection portion 14 without passing through wiring of the mounting board 6, so that the distance can be shortened and a high-frequency signal can be transmitted.

Furthermore, the optical fiber 8 is inserted from a lateral direction, so that the optical interface module 7 can be formed thinner. Accordingly, with respect to the interposer 3, the height of an upper surface of the optical interface module 7 can be made lower than that of an upper surface of the signal processing LSI 2, which makes it easy to secure an installation space of a large heat sink for the signal processing LSI 2. Moreover, it is also possible to add fixing strength by inserting an adhesive into a gap between the loop electrodes 16 or between the plate electrodes 20.

Moreover, as shown in FIG. 4, a positioning guide pin 25 to accurately determine relative positions of opposed electrodes may be added. In this case, a guide pin hole 26 fittable with the positioning guide pin 25 is provided in the interposer 3 and the positioning guide pin 25 is fitted into the guide pin hole 26, thereby making it possible to not only accurately determine the positions of the opposed electrodes but also increase mechanical strength for holding the relative positions between the optical interface module 7 and the interposer 3 when external force is applied.

### Second Embodiment

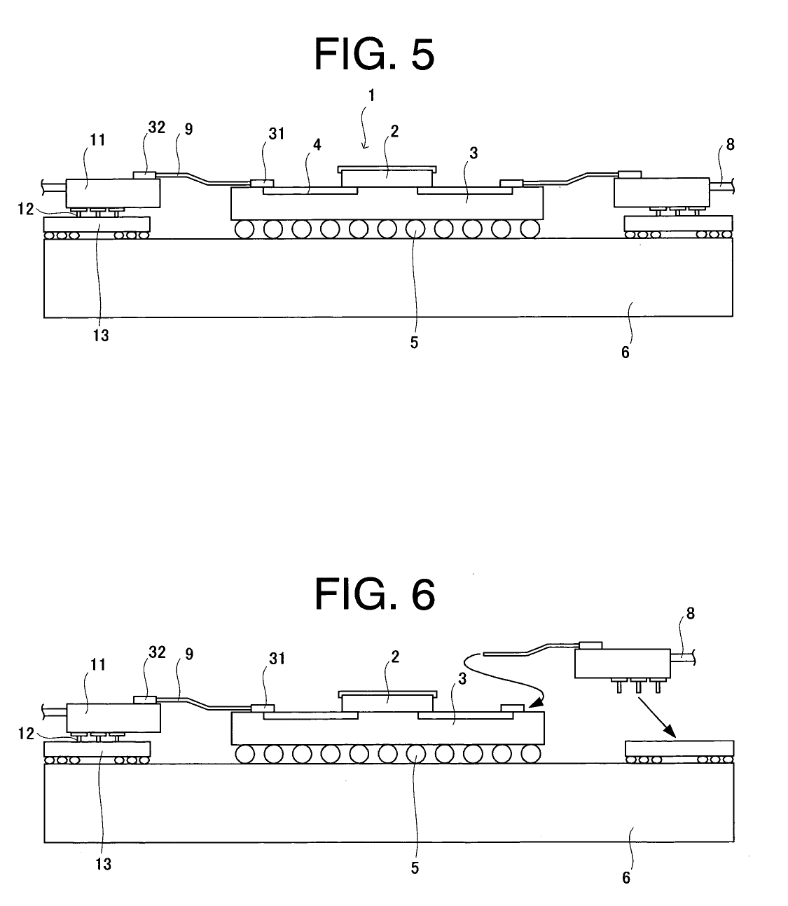

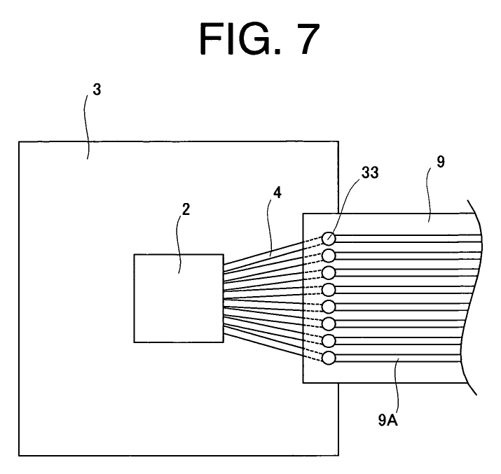

FIG. 5 is a view showing a schematic structure of an LSI package with an interface module according to a second embodiment of the present invention, FIG. 6 is a view showing a connecting process of an optical interface module according to the second embodiment of the present invention, and FIG. 7 shows a top view of an interposer with an FPC according to the second embodiment of the present invention. Incidentally, the same portions as shown in FIG. 1 are denoted by the same numerals and symbols, so that the detailed description thereof will be omitted.

As shown in FIG. 5, an FPC connector 31 (an electrical connector) is mounted on the interposer 3, and an FPC connector 32 (an electrical connector) is mounted on the optical interface module 7. Both ends of the FPC 9 are connected to the FPC connectors 31 and 32, respectively, and electrically connected to an electrical connection terminal (not shown) of the interposer 3 and an electrical connection terminal (not shown) of the optical interface module 7 via the FPC connectors 31 and 32.

To mount such an LSI package with the interface module 1 on the mounting board 6, first, the interposer 3 on which the signal processing LSI 2 and the FPC connector 31 are mounted is electrically connected to the mounting board 6 by the connection terminals 5. At this time, preferably simultaneously with the above, the socket 13 and other mounting components are mounted on the mounting board 6. Thereafter, as shown in FIG. 6, the input/output pins 12 of the optical interface module 7 on which the FPC connector 32, to which one end of the FPC 9 is connected, is mounted are inserted into the socket 13, and the other end of the FPC 9 is connected to the FPC connector 31 by being inserted thereinto.

This structure also makes it possible to mount the interposer 3 and the socket 13 on the mounting board 6, thereafter connect a power supply of the optical interface module 7, a low-speed control signal, and soon by insertion into the socket 13, and connect with the high-speed signal wire 4 by the FPC 9, whereby a structure highly suitable for conventional reflow mounting can be provided.

Incidentally, both the FPC connectors 31 and 32 are not necessarily required, and if either the FPC connector 32 on the optical interface module 7 side or the FPC connector 31 on the interposer 3 side is provided, the optical interface module 7 can be mounted later. For example, when only the FPC connector 32 is provided, as shown in FIG. 7, on the interposer 3 side, electrode wires 9A of the FPC 9 have only to be directly connected to the high-speed signal wires 4 by a conductive adhesive, Au stud bumps 33, or the like.

Moreover, a positioning guide pin to accurately determine relative positions of opposed electrodes may be added onto the interposer 3. In this case, a guide pin hole fittable with the positioning guide pin is provided in the FPC 9 and the positioning guide pin is fitted into the guide pin hole, thereby making it possible to not only accurately determine the positions of the opposed electrodes but also increase mechanical strength for holding the relative positions between the FPC 9 and the interposer 3 when external force is applied.

### Third Embodiment

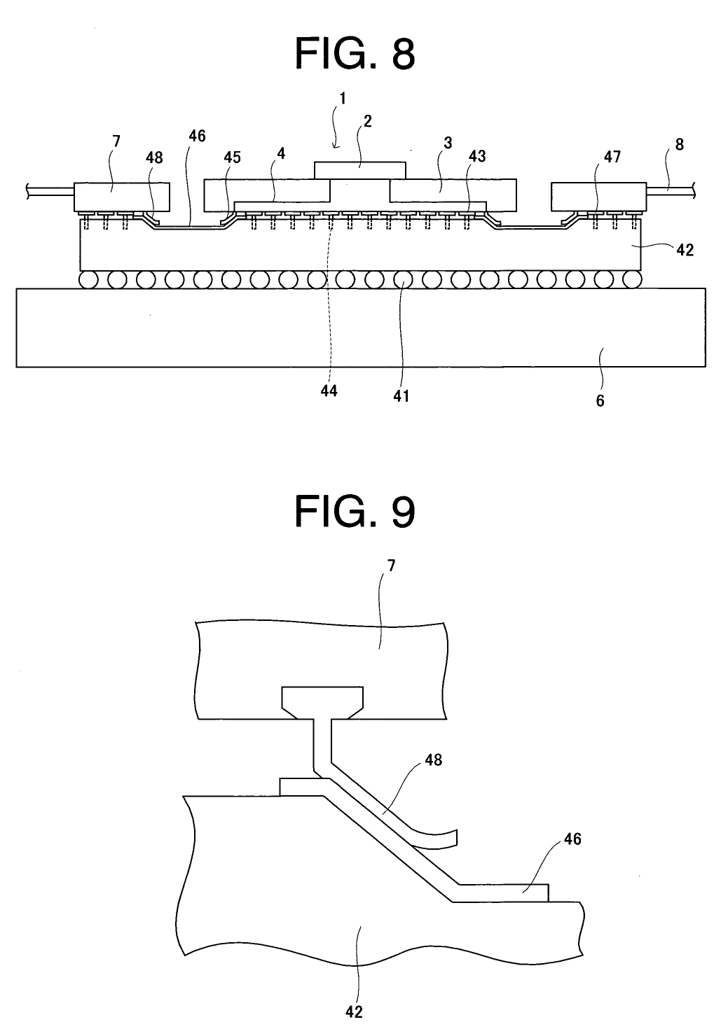

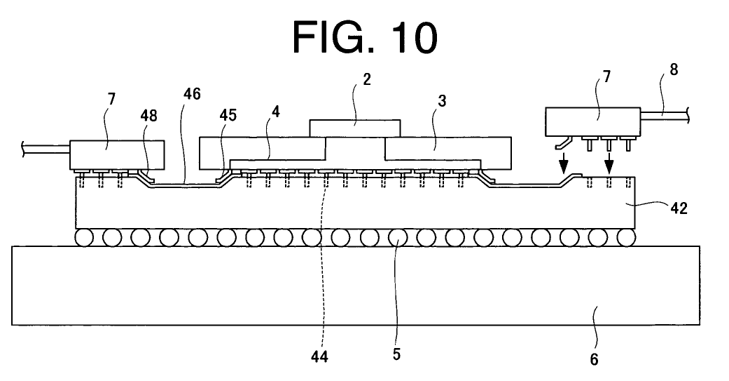

FIG. 8 is a view showing a schematic structure of an LSI package with an interface module according to a third embodiment of the present invention, FIG. 9 is an enlarged view of a connection portion of a high-speed signal wire according to the third embodiment of the present invention, and FIG. 10 is a view showing a connecting process of an optical interface module according to the third embodiment of the present invention. Incidentally, the same portions as shown in FIG. 1 are denoted by the same numerals and symbols, so that the detailed description thereof will be omitted.

As shown in FIG. 8, in this embodiment, the interposer 3 is connected to a socket 42, which is connected to the mounting board 6 by solder bumps 41, by input/output pins 43 (a socket connection terminal pin). More specifically, jacks 44 fittable with the input/output pins 43 are formed in the socket 42, and by fitting the input/output pins 43 into the jacks 42, the interposer 3 is connected to the socket 42. The input/output pins 43 are to perform input/output to supply a low-speed signal of several hundred megahertz or less, a control signal, a power supply, and so on.

The high-speed signal wire 4 is not drawn out to a surface on which the signal processing LSI 2 is mounted (an upper surface) of the interposer 3 side, but connected to a high-speed signal electrical terminal 45 installed on the socket 42 side. The high-speed signal electrical terminal 45 is connected to the high-speed signal wire 46 by being pressed thereto. In the optical interface module 7, as in the interposer 3, a low-speed signal and a power supply are connected by input/output pins 47, and only the high-speed signal is connected to the high-speed signal wire 46 by a high-speed signal electrical terminal 48.

When the input/output pins 47 of the optical interface module 7 are inserted into the jacks 44 of the socket 42, as shown in FIG. 8, the high-speed signal electrical terminal 48 comes into contact with the high-speed signal wire 46 and receives force of sliding in the lateral direction, whereby it functions as a spring and is pressed against the high-speed signal wire 46 by restoring force. Since the input/output pins 47 are inserted into the jacks 44, restoration of the spring is hindered, so that the restoring force is maintained, and connection is maintained. This goes for the high-speed signal electrical terminal 45 on the interposer 3 side.

To mount such an LSI package with the interface module 1 on the mounting board 6, first, the socket 42 is mounted on the mounting board 6. At this time, preferably, simultaneously with the above, other mounting components are mounted on the mounting board 6. Thereafter, as shown in FIG. 10, the high-speed signal electrical terminals 45 and 48 of the interposer 3 on which the signal processing LSI 2 is mounted and the optical interface module 7 and the high-speed signal wire 46 are aligned, and the input/output pins 43 and 47 are fitted into the jacks 44.

This structure also makes it possible to mount the socket 42 for the interposer 3 on the mounting board 6 and thereafter attach the interposer 3 and the optical interface module 7 without adding heat treatment and so on, whereby the LSI package with the interface module 1 which can be mounted without interfering with conventional board mounting can be provided.

Further, according to this structure, if a mechanism for preventing pins from coming off is provided in the socket 42, it is unnecessary to specially provide a fixing member additionally in the exterior, whereby a highly reliable structure can be realized by a simple structure.

Furthermore, as in the first embodiment, a positioning guide pin to accurately determine relative positions of opposed electrodes may be added to the interposer 3. In this case, a guide pin hole fittable with the positioning guide pin is provided in the socket 42 and the positioning guide pin is fitted into the guide pin hole, thereby making it possible to not only accurately determine the positions of the opposed electrodes but also increase mechanical strength for holding the relative positions between the interposer 3 and the socket 42 when external force is applied.

### Fourth Embodiment

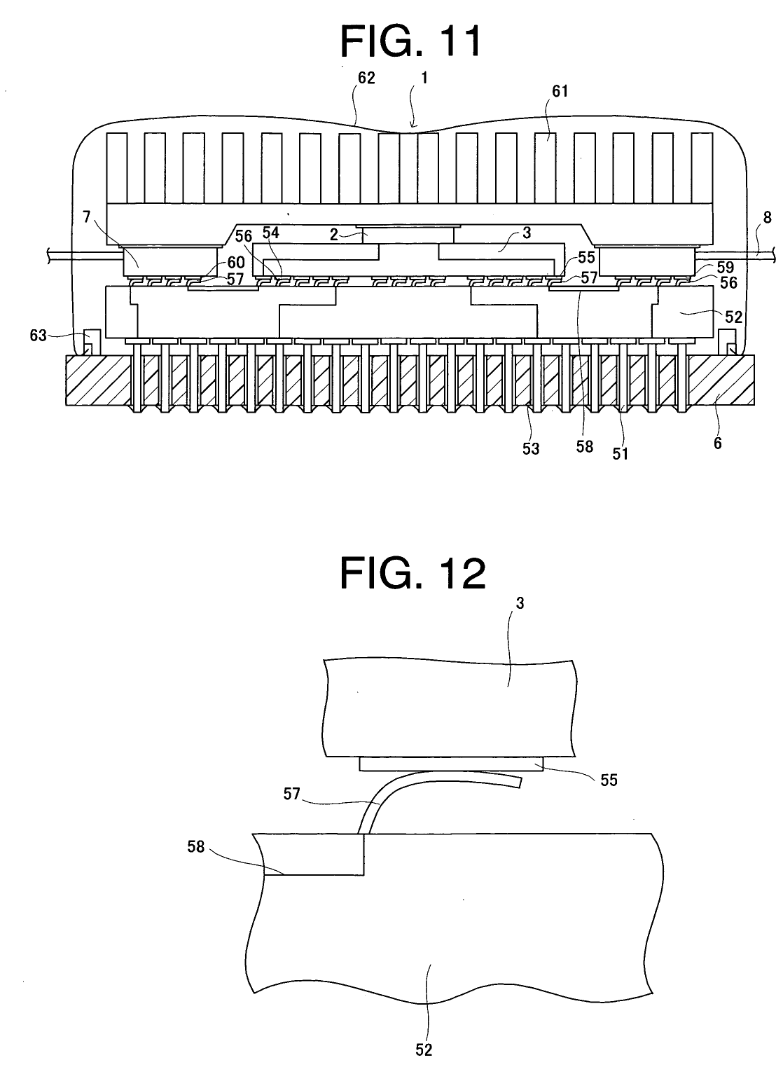

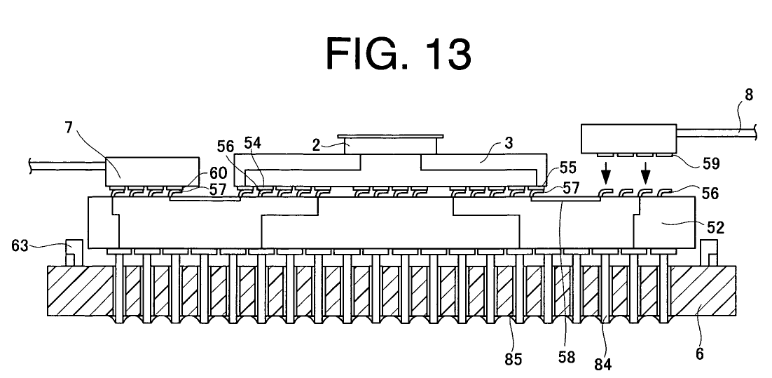

FIG. 11 is a view showing a schematic structure of an LSI package with an interface module according to a fourth embodiment of the present invention, FIG. 12 is an enlarged view of a connection portion of a high-seed signal wire according to the fourth embodiment of the present invention, and FIG. 13 is a view showing a connecting process of an optical interface module according to the fourth embodiment of the present invention. Incidentally, the same portions as shown in FIG. 1 are denoted by the same numerals and symbols, so that the detailed description thereof will be omitted.

As shown in FIG. 11, in this embodiment, the interposer 3 is connected to a socket 52, which is connected to the mounting board 6 by connection pins 51. The mounting board 6 and the connection pins 51 are fixed by solders 53.

On a connection surface on the socket 52 side of the interposer 3, lands 54 (a socket connection electrical terminal) and lands 55 (a high-speed signal electrical terminal) are formed. On an upper surface of the socket 52, connection terminals 56 to come into contact with the lands 54 is provided. By making the lands 54 come into contact with the connection terminals 56, the interposer 3 is electrically connected to the mounting board 6 via the connection terminals 56 and the connection pins 51. The high speed wire 4 of the interposer 3 is connected to a high-speed signal wire 58 formed in the socket 52.

On a connection surface on the socket 52 side of the optical interface module 7, a land 59 (a socket connection electrical terminal) and a land 60 (high-speed signal electrical terminal) are formed. By making the land 59 come into contact with the connection terminal 56, the optical interface module 7 is electrically connected to the mounting board 6 via the connection terminal 56 and the connection pins 51, and the low-speed signal, the control signal, the power supply, and so on are supplied. A land 60 of the optical interface module 7 is connected to the high-speed signal wire 58 formed in the socket 52 via the connection terminal 57.

As shown in FIG. 12, the connection terminals 55 and 56 each have a flexible spring structure, and generate pressure by restoring force by the land 54 and the like being pressed by contact. Accordingly, as shown in FIG. 11, this structure needs a pressing mechanism 62, which presses the interposer 3 and the optical interface modules 7 together with a heat sink 61 and so on toward the socket 52. The pressing mechanism 62 is a mechanism which presses the heat sink 61 toward the mounting board 6 by engaging with a retention jig 63 formed on the mounting board 6, thereby pressing the interposer 3 and the optical interface modules 7 simultaneously toward the socket 52, and holding pressing force for electrical connection.

To mount such an LSI package with the interface module 1 on the mounting board 6, first, the socket 52 is mounted on the mounting board 6. At this time, preferably simultaneously with the above, other mounting components are mounted on the mounting board 6. Thereafter, as shown in FIG. 12, the lands 55 and 60 of the interposer 3 on which the signal processing LSI 2 is mounted and the optical interface module 7 and the high-speed signal wire 58 are aligned, and the lands 54 and so on are pressed on the connection terminals 56 and 57. Thereafter, the pressing mechanism 62 is attached to hold the pressing force.

This structure is characterized in that the terminals for the high-speed signal, the low-speed signal, the power supply, and soon can have the same structure, so that the structure of the socket 52 and the structures of the interposer 3 and the optical interface module 7 are simplified, resulting in a reduction in cost, and since pin connection is not used, input/output terminals can be densified.

Moreover, this structure also makes it possible to mount the socket 52 for the interposer 3 on the mounting board 6 and thereafter attach the interposer 3 and the optical interface module 7 without adding heat treatment and so on, whereby the LSI package with the interface module 1 which can be mounted without interfering with conventional board mounting can be provided.

Moreover, as in the first embodiment, a positioning guide pin to accurately determine relative positions of opposed electrodes may be added to the interposer 3. In this case, a guide pin hole fittable with the positioning guide pin is provided in the socket 52 and the positioning guide pin is fitted into the guide pin hole, thereby making it possible to not only accurately determine the positions of the opposed electrodes but also increase mechanical strength for holding the relative positions between the interposer 3 and the socket 52 when external force is applied.

### Fifth Embodiment

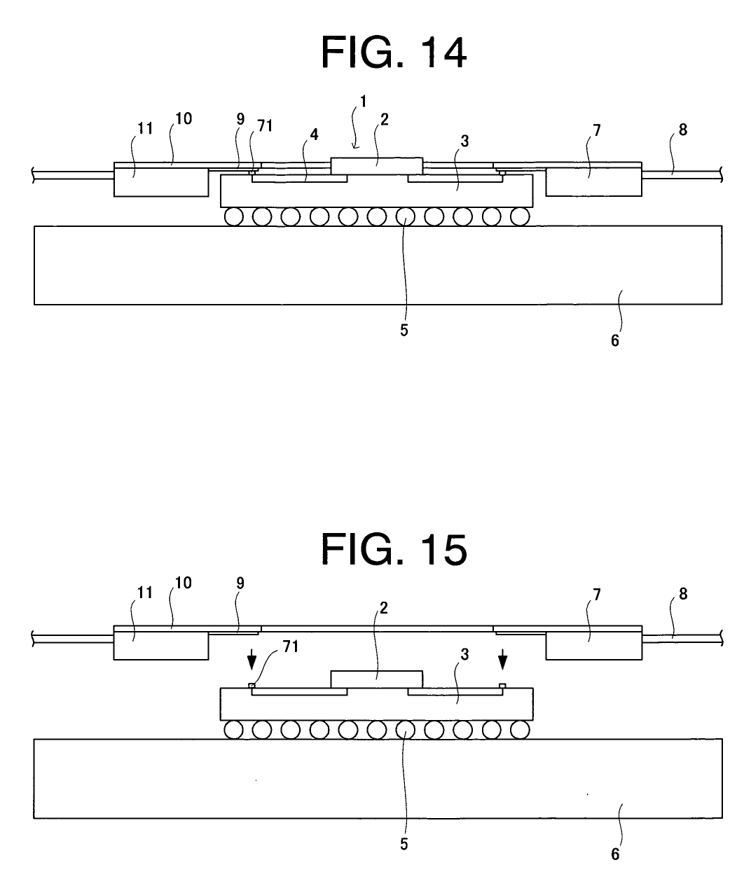

FIG. 14 is a view showing a schematic structure of an LSI package with an interface module according to a fifth embodiment of the present invention, and FIG. 15 is a view showing a connecting process of an optical interface module according to the fifth embodiment of the present invention. Incidentally, the same portions as shown in FIG. 1 are denoted by the same numerals and symbols, so that the detailed description thereof will be omitted.

As shown in FIG. 14, this embodiment is characterized in that an electrical connection terminal (not shown) connected to the high-speed signal wire 4 of the interposer 3 and an electrical connection terminal (not shown) of the optical interface module 7 are connected by a solder 71 with a lower melting point than a board mounting solder. Here, the board mounting solder is, for example, a solder ball in the case of BGA and so on, and, for example, a solder to fix a pin and a mounting board in the case of PGA and so on. In this embodiment, the connection terminals 5 are the board mounting solder. The solder 71 is, for example, a Sn—Bi—Ag or Sn57Bi low-melting point solder. In these solder compositions, the melting point is approximately 150° C. or lower, which enables mounting without interfering with mounting of the interposer 3 and exerting a bad influence on optical elements and optical components, especially a fixing member which holds an optical fiber included in the optical interface module 7. Therefore, the LSI package with the interface module 1 highly suitable for electrical mounting can be provided with a very simple structure. It is desirable to use a resin as the optical fiber fixing member to reduce the cost, but when the resin is used, it becomes difficult to accurately hold the optical fiber 8 if the process temperature becomes higher than a softening point of the resin. In the case of solder mounting, it is necessary to set the mounting temperature higher than a melting point of solder metal so as to prevent the influence of sufficient wettability, the device, and a change in the environment, and to advance the process in a period of time which does not matter in practical application, an overshoot of 10° C. to 20° C. from the solder melting point is inevitable. Accordingly, when the melting point of the solder 71 is higher than a temperature which is lower than the softening point of the fixing member for the optical fiber 8 by 20° C., it is desirable that the melting point of the solder 71 is lower than the softening point of the fixing member by 20° C. since there is a risk of the mounting temperature exceeding the softening point by overshoot.

To mount such an LSI package with the interface module 1 on the mounting board 6, first, the interposer 3 on which the signal processing LSI 2 is mounted is electrically connected to the mounting board 6 by the connection terminals 5. Then, the optical interface module 7 is aligned with the interposer 3, and thereafter, as shown in FIG. 15, the electrical connection terminals of the interposer 3 and the electrical connection terminals of the optical interface modules 7 are connected by the solders 71.

The present invention is described by the above embodiments, but it should not be understood that the description and drawings which form a part of this disclosure limit the present invention. Various alternative forms, embodiments and operation techniques will be apparent to those skilled in the art from this disclosure.

For example, the examples in each of which one to two optical interface modules 7 are mounted are shown, but there is no limit to the number thereof, and such an architecture that one to two optical interface modules are mounted at each of four sides of the interposer 3 is also possible. Further, the pressing mechanism 62 of the fourth embodiment may be inserted between the heat sink, and the interface module and the interposer, and in this case, the heat sink can be fixed using another fixing member. As just described, it is a matter of course that the present invention includes various embodiments which are not described here. Furthermore, the present invention can be embodied in various modified forms without departing from the spirit of the present invention.

As described in detail above, according to the first embodiment to the fifth embodiment, the pig-tail type interface module (a structure in which one end of the transmission line is included in the interface module) is used as the interface module and housed together with an optical coupling or an electrical connection holding structure in another package to reduce the size, and the interface module and the interposer are electrically connected via the electrical connection terminals provided therein. This can eliminate problems in terms of mounting such as cost increase and interference of soldering caused by complication of the structure, and consequently, the LSI package with the interface module capable of realizing an increase in the throughput of the interface can be provided.

More specifically, since no high-speed signal wire is provided in the mounting board, the electrical wiring length between the signal processing LSI and the interface module can be shortened, and therefore, no expensive transmission line is needed for mounting the high-throughput interface module. Further, since external wiring of the interface module is directly coupled instead of coupling by a connector, the structure of the interface module does not become complicated. In addition, the interposer and the interface module can be coupled to each other by the electrical connection terminals, which eliminates the problem such as the interference between the soldering of the interposer and the soldering of the interface module.

Next, the main points of other aspects of the present invention described below deal with the relation between the extra length and the deflection of the transmission line quantitatively, and solve the above-described problems by limiting the extra length and appropriately processing a deflection portion. Hereinafter, embodiments of the present invention will be described with reference to the drawings. Although the example in which an optical fiber is mainly used as the transmission line is shown in the embodiments, it is needless to say that a small-diameter coaxial line is also usable.

### Sixth Embodiment

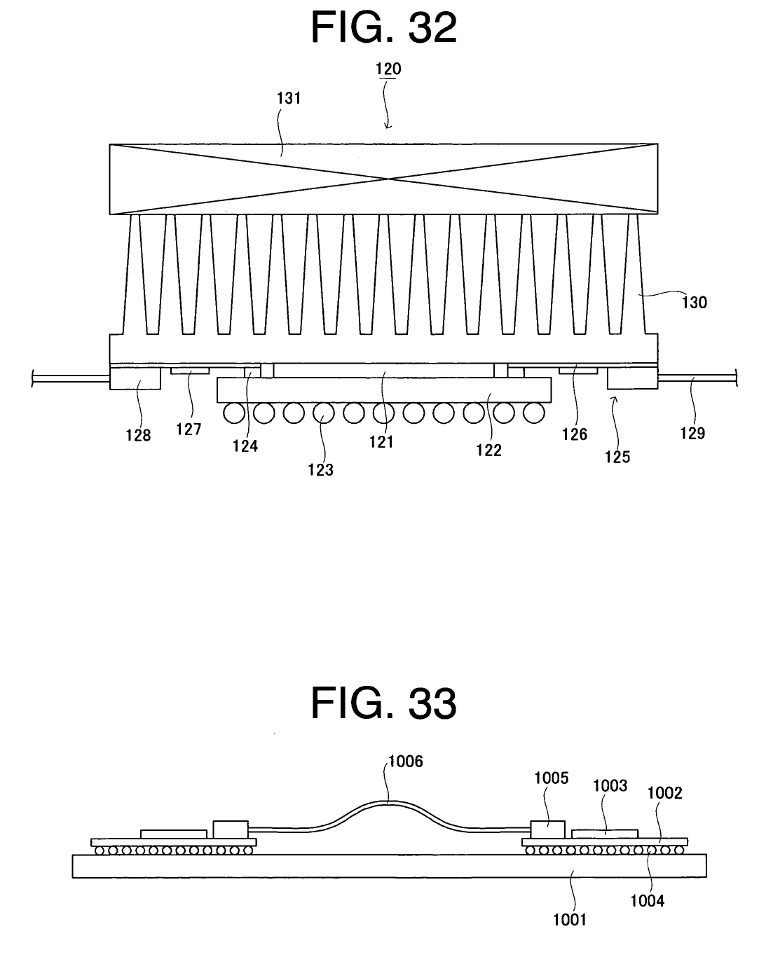

FIG. 32 is a schematic structural view of an LSI package with an interface module in a sixth embodiment. In FIG. 32, numeral 120 denotes an LSI package with an interface module, numeral 121 denotes a signal processing LSI, numeral 122 denotes an interposer board, numeral 123 denotes a solder ball, numeral 124 denotes an electrical connection terminal, numeral 125 denotes an interface module, numeral 126 denotes a wire, numeral 127 denotes an optical element driving IC, numeral 128 denotes a photoelectric converter, numeral 129 denotes an optical fiber (an optical transmission line), numeral 130 denotes a heat sink, and numeral 131 denotes a cooling fan.

The interposer 122 includes the solder balls 123 to electrically connect with a mounting board (not shown) and the electrical connection terminals 124. The interface module 125 is composed of an electrical connection terminal (not shown) which is electrically connected to the electrical connection terminal 124 by mechanically coming into contact with the electrical connection terminal 124, the wire 126, the optical element driving IC 127, the photoelectric converter 128, and the optical fiber 129.

A high-speed signal from the signal processing LSI 121 is not supplied to the mounting board through the solder balls 123 but supplied to the optical element driving IC 127 through the electrical connection terminal 124 and the wire 126. Then, the high-speed signal is converted into an optical signal by the photoelectric converter 128 and given to the optical fiber 129. Incidentally, signals other than the high-speed signal are supplied to the mounting board through the solder balls 123.

This package allows the interface module 125 to be mounted later on the interposer board 122 on which the signal processing LSI 121 is mounted. Further, the heat sink 130 and the cooling fan 131 are mounted thereon, whereby heat release of the signal processing LSI 121 becomes possible.

As concerns the LSI package with the interface module 120 thus structured, board mounting becomes possible in exactly the same procedure and exactly the same conditions as when an LSI is mounted on a mounting board fabricated by an existing production line by using an existing mounting device (such as a reflow device). Namely, the structure in FIG. 32 can be constructed on the mounting board if the interposer board 122 on which the signal processing LSI 121 is previously mounted is mounted together with other electronic components on the mounting board by an existing method, and thereafter the interface modules 125 are put from above and fixed (for example, by screws or an adhesive). At this time, until the process of board mounting of the interposer board 122, production is possible without changing an existing mass production line at all, and an operation unique to constructing an optical wiring board is only an operation of mounting the interface modules 125. Moreover, the process of putting the interface modules 125 from above and fixing them does not need special high-precision alignment (for example, ±10 μm), and the precision of a common electrical connector is sufficient for this process, whereby the cost of the mounting process is not increased so much. Namely, using an existing inexpensive mounting board (such as a glass epoxy board) and an existing mounting method, a high-speed board including high-speed wiring (for example, 20 Gbps per wire) which is generally difficult to realize by board electrical wiring can be realized.

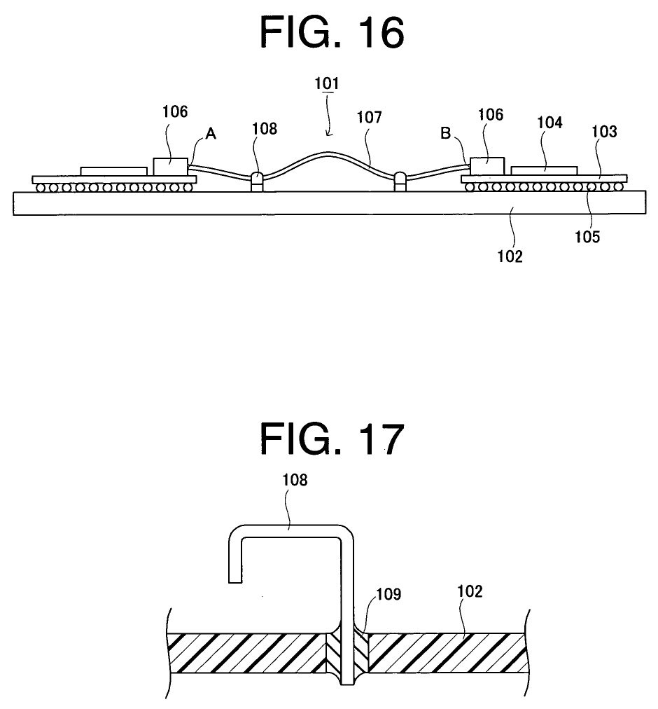

A deflection of aerial wiring of a transmission line 1006 such as shown in FIG. 33 is unexpectedly large, and the fact that, for example, in the case of a wiring length of 20 cm, a deflection as large as approximately 9 mm occurs with respect to an error of only 1 mm (a transmission line length of 201 mm) is obtained from the result of actual measurement by the inventors. Although the quantitative analysis thereof will be described later, 1 mm with respect to 20 cm is an error of only 0.5%, which is not so extremely large as an ordinary manufacturing error. However, it turns out that as the effect thereof (deflection height), a change of approximately 4.5% which is almost ten times appears. Leaving this as it is exerts a serious influence on reliability and so on as a package such as described above. An embodiment to solve this is shown in FIG. 16.

FIG. 16 is a schematic structural view of a transmission line package in the sixth embodiment of the present invention, and two right and left LSI packages each with an interface module are mounted on the same mounting board (a board) and high-speed wiring between them is performed by aerial wiring of a transmission line. In FIG. 16, numeral 101 denotes a transmission line package, numeral 102 denotes a mounting board, numeral 103 denotes an LSI package substrate (such as an interposer), numeral 104 denotes an LSI chip, numeral 105 denotes a solder ball, numeral 106 denotes an interface module, numeral 107 denotes an optical fiber, and numeral 108 denotes a hook.

The LSI package substrate 103 is mounted on the mounting board 102 via the solder balls 105, and the LSI chip 104 and the interface module 106 are mounted on the LSI package substrate 103. The interface modules 106 are connected by the optical fiber 107.

The optical fiber 107 is aerially wired from a first wiring point A on the mounting board 102 to a second wiring point B on the mounting board 102. The length of the optical fiber 107 is longer than the shortest wiring length between the first wiring point A and the second wiring point B by a range not less than 2% nor more than 20% of the shortest wiring length.

The optical fiber 107 is hooked by the hooks 108 which pull the optical fiber 107 toward the mounting board 102. More specifically, the optical fiber 107 is hooked by the hooks 108 in such a manner that the height of a portion of the optical fiber 107 hooked by the hook 108 becomes equal to or lower than the height of straight-line wiring from the first wiring point A to the second wiring point B. If there is a vacant space on the surface of the mounting board 102, instead of the hook 108, a structure in which the optical fiber 107 is fixed to the mounting board 102 by a fixing member such as a double-sided adhesive tape may be adopted.

FIG. 17 is a view showing an example of attachment of the hook 108 to the mounting board 102, and the hook 108 is an L-shaped pin (hook-shaped pin) at a tip of which a hook portion is formed. The hook 108 is fixed to a through hole formed in the mounting board 102 by a solder 109. The hook 108 may be fixed by a screw, but in the case of soldering such as shown in FIG. 17, the hook 108 can be easily fixed together with other components by solder reflow.

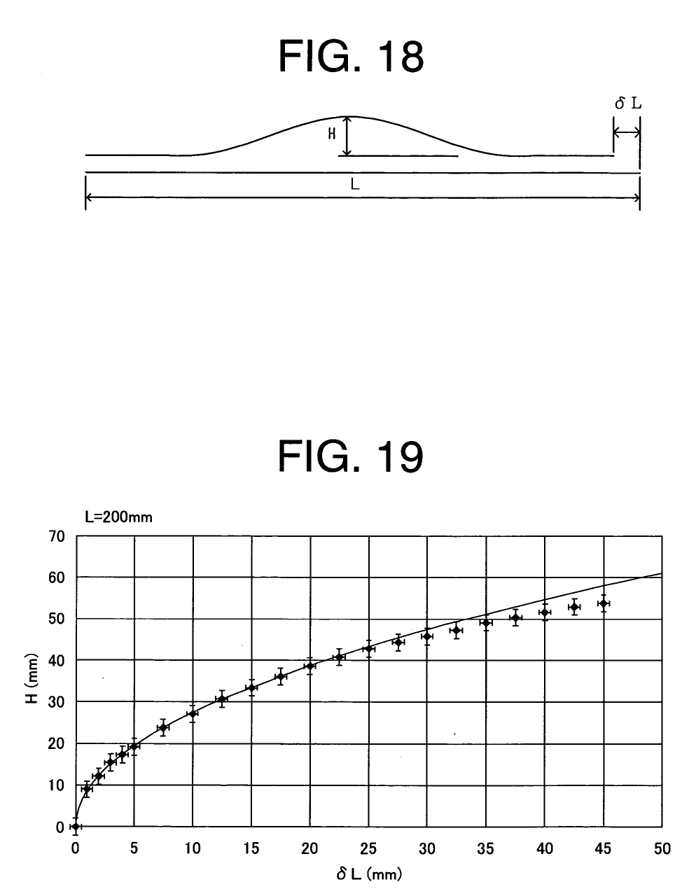

What kind of effect is produced by the structure such as shown in FIG. 16 will be described using FIG. 18 and FIG. 19. FIG. 18 is an explanatory view explaining a deflection of the optical fiber in the sixth embodiment, and FIG. 19 is a graph showing calculation results of the deflection amount of the optical fiber in the sixth embodiment. Also in the case of an array fiber such as a ribbon optical fiber, almost the same results can be obtained when the deflection occurs only in a direction orthogonal to an array arrangement direction.

First, as shown in FIG. 18, an original length of the aerially wired optical fiber (ribbon) is defined as L. A height of a deflection of the optical fiber buckled by being pressed in an axial direction is defined as H, and a distance by which an end of the optical fiber is moved by being pressed is defined as δL. The precise value of a curve of such a deflection is found by solving a deflection differential equation, but assuming that the thickness of the optical fiber ribbon is approximate to an ideal value (a thickness of zero) and the length thereof does not change before and after the buckling, an approximation is made by combining three curves with the same curvature, thereby obtaining an appropriate relational expression of H=SQRT(L·δL·3/8). Here, SQRT represents a square root. The graph in FIG. 19 shows results of finding deflection heights when L=20 cm by this approximate expression, and actual measurement results (deflection heights of a ribbon sheet 0.1 mm in thickness) are shown at the same time using points each with an error range.

From these results, it turns out that the above approximate expression practically agrees with the actual measurement results from 0.5% (δL=1 mm) to 10% (δL=20 mm) of L, which is an approximation sufficient to analyze behavior up to the order of 15% (δL=30 mm). In the above approximate expression, a series expansion approximation is performed on a trigonometric function part in a derivation process, and errors in portions where δL is large in FIG. 19 are thought to be the same results as errors caused by approximations (sin θ to θ) of the trigonometric function.

It is found from FIG. 19 that the rate of change of the deflection amount caused by the wiring length error is large in a range with small wiring length errors and small in a range with large wiring length errors, the relationship therebetween is almost proportional to the square root of the wiring length error, and so on. Moreover, it is found that since the absolute value of the deflection amount is also proportional to the square root of the wiring length from the above-described approximate expression, the deflection amount can be reduced by reducing the absolute value of the wiring length. Returning now to this embodiment, in FIG. 16, the deflection is held by cramping the optical fiber 107 by the hooks 108 at two points. Applying the above to a concrete case, an example will be shown.

With recent development of a broadband access network, the so-called IT (Information Technology) industry such as an information providing service has very rapidly developed. A data server is important here, and an array server is in high demand as a system capable of withstanding various simultaneous accesses from a huge number of users. The array server is a system to enormously increase overall data delivery efficiency by bringing several tens to several hundreds of data servers with a medium level of capacity (up to 100 GB) into operation to respond to many kinds of data requests in parallel operation instead of storing and delivering huge data by one server. To build such an array server, a very large installation space is required, and the number of housed servers per unit space becomes an important factor of a service cost. Hence, a hardware form of the array server used commonly is a blade server, which is an array server of a type in which many unit servers (blades) in which all server system functions are housed inone board are mounted in parallel in a rack to densify the number of servers.

For the densification of the blade server, a blade with 1U (mount unit standard 1.75 in, 44.45 mm) in width has been recently used. To build the server system within 1U, double-sided mounting on the board is indispensable, and assuming that the mechanical case housing allowance of the blade is 5 mm, and the total of a mounting board thickness and a soldering height is approximately 5 mm, the board mounting height is approximately 35 mm, and the maximum mounting height is approximately 17.5 mm in double-sided uniform arrangement. If the LSI package with the interface module in FIG. 16 is mounted thereon and the wiring length thereof is 20 cm, the deflection height of the transmission line becomes 17.3 mm from FIG. 19 even if the allowance of the wiring length is reduced to 2% (4 mm) as a controllable minimum value, and thus when the thickness of the LSI package and the thickness of the interface module are taken into consideration, several millimeters come to be outside the range capable of being housed in 1U. Accordingly, in prior arts, it is necessary to take the following measure: the wiring length error is controlled more strictly, for example, at 1% (2 mm) or less, or the wiring length is limited to 10 cm at the maximum and the wiring length error is controlled at 4% (4 mm) or less, but in this case, there are few practical advantages of aerial wiring of the transmission line.

In contrast, the present invention has no problem, for example, even if the wiring length is set to 20 cm or more, and the wiring length allowance is 4 mm or more. Namely, by hooking portions of the transmission line as shown in FIG. 16, the absolute value of the deflection height can be held down. As an example, when the wiring length L is 20 cm and the wiring length error δL is 4 mm, the deflection height H in a free state is 17.3 mm. But when a hook is placed at a position such that a straight-line distance between the first wiring point A and the second wiring point B is divided into two equal parts and the transmission line is hooked by the hook so that the transmission line is of the same height, two protuberances are formed by the deflection of the transmission line, and the deflection height H of each protuberance becomes 8.7 mm (equal to when L=10 cm, δL=2 mm). When, from this state, the transmission line is pulled toward one protuberance in such a manner that the deflection height of the other protuberance becomes H=0, the number of protuberances becomes one, and the deflection height H of this protuberance becomes 12.2 mm (equal to when L=10 cm, δL=4 mm). Both are the deflection heights within the range capable of being housed in 1U. Incidentally, it is needless to say that even when the transmission line is pulled so that the deflection height of the protuberance opposite to the above becomes H>0, similarly the deflection height does not exceed 12.2 mm.

Further, when hooks are placed at positions such that the straight-line distance between the first wiring point A and the second wiring point B is divided into three equal parts and the transmission line is hooked by the hooks so that the transmission line is of the same height as shown in FIG. 16, three protuberances are formed by the deflection of the transmission line, and the deflection height H of each protuberance becomes 5.8 mm (equal to when L=6.7 cm, δL=1.3 mm). When, from this state, the transmission line is pulled toward one remaining protuberance in such a manner that the deflection heights of the other two protuberances become H=0, the number of protuberances becomes one, and the deflection height H of this protuberance becomes 10 mm (equal to when L=6.7 cm, δL=4 mm). Both are the deflection heights within the range capable of being housed in 1U. Incidentally, it is needless to say that even when deflections are concentrated onto any protuberance, the deflection height does not exceed 10 mm which is the deflection height when the transmission line is pulled toward one protuberance. This enables aerial wiring of the transmission line at a deflection height sufficiently lower than the above-described maximum mounting height for 1U.

Incidentally, to minimize the deflection height by plural hooks, it is required to divide the wiring length error equally between the respective hooks, but to this end, a method of equally dividing the transmission line and fixing the transmission line to the mounting board using a double-sided adhesive tape or the like is more reliable than the method of using the hooks. However, when there is no space for fixing on the surface of the mounting board, it is also possible to fix the transmission line to the hooks at positions lifted from the board surface by the heights of mounted components or fix the transmission line onto upper portions of components mounted on fixing portions.

Next, a marginal example of examples in which the deflection height is held down in the same manner when the wiring length error is increased will be shown. If the wiring length error δL is increased and the number of hooks is increased, the deflection curvature of a deflection portion decreases. Therefore, the transmission line such as the optical fiber whose minimum curvature is determined needs to be set to this curvature or less. For example, if in the example of a wiring length of 20 cm, the wiring length error is 20% (δL=40 mm), the wiring length (distance on the board) and the transmission line length L become clearly different, and hence the need for making a calculation with L being strictly set to L=240 mm (that is, L=240 mm, δL=40 mm instead of L=200 mm, L=40 mm) arises. In this case, the free deflection height is 60 mm in the above-described approximate expression, and approximately 54 mm in actual measurement, so that the application of the approximate calculation expression becomes difficult. Therefore, the description will be given mainly using actual measurement results. As a result of a study of conditions to perform 1U mounting as described above, it is found that if the hooks are installed at four positions and the transmission line is equally divided, that is, the transmission is fixed by the hooks at a height of H=0, in actual measurement, the maximum deflection height becomes 15 mm (equal to when L=60 mm, δL=10 mm, wiring length of 50 mm) which is the highest possible height capable of being housed in 1U mounting. However, if the deflection curvature at this time is examined, it turns out that it is a radius of approximately 14 mm. This value is smaller than 30 mm which is a minimum guaranteed bend radius of a common optical fiber, and a little smaller than 15 mm which is a minimum guaranteed bend radius of a high bending resistant fiber optimized for indoor wiring. Accordingly, in terms of the characteristic of the optical fiber, the wiring length error more than this is not desirable, and it is appropriate to set the wiring length error to 20% or less as described above.

As described above, it is desirable to limit the scope of application of the present invention to the wiring length error of 2% or more of the wiring length in terms of the control of the wiring length and the handling of the transmission line and 20% or less of the wiring length in terms of a limit of the deflection curvature of the transmission line. Further, it is more desirable that the transmission line falls within a range not less than 4% nor more than 10% of the wiring length.

### Seventh Embodiment

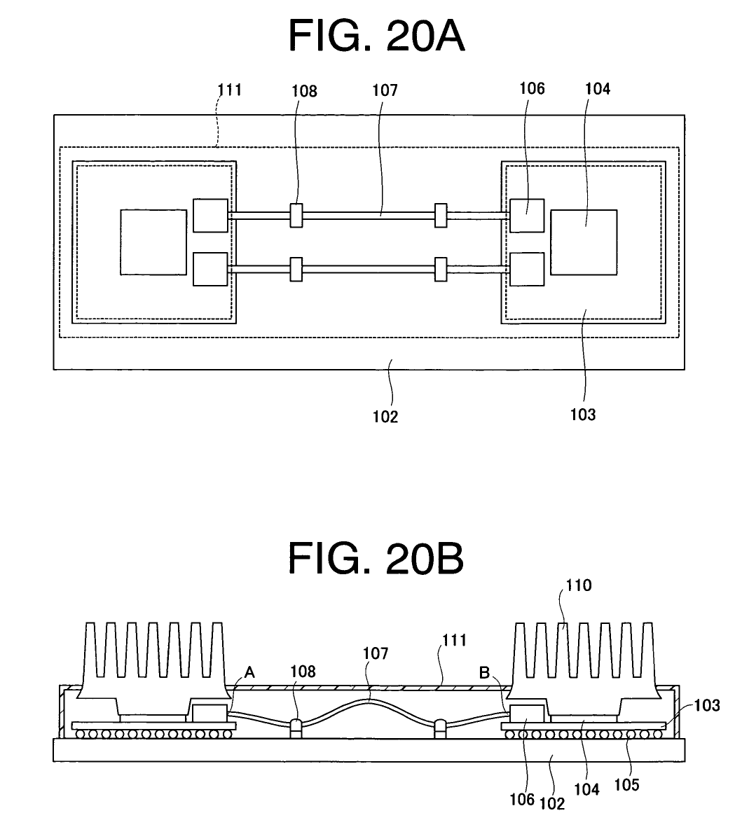

FIG. 20A is a top view showing a schematic structure of a transmission line package in a seventh embodiment of the present invention, FIG. 20B is a cross-sectional view showing a schematic structure of the transmission line package in the seventh embodiment of the present invention, and both show an example in which a deflection portion of the aerially wired transmission line is prevented from being vibrated and damaged by cooling air from a cooling fan. In FIG. 20A and FIG. 20B, numeral 110 denotes a heat sink, numeral 111 denotes a windbreak cover, and the others are the same as those in the six embodiment.

In place of the hook 108, a structure in which the optical fiber 107 is fixed to the mounting board 102 by a fixing member such as a double-sided adhesive tape is also usable if there is a vacant space on the surface of the mounting board 102. As shown in FIG. 20A and FIG. 20B, the heat sink 110 is closely attached to the LSI chip 104 by a retainer (not shown) or the like and may further include the cooling fan 131 as shown in FIG. 32.

The windbreak cover 111 is provided in a region from the first wiring point A to the second wiring point B. The windbreak cover 111 may be a molded article of low-cost resin such as polyethylene resin or recycled resin of PET bottles and has openings (windows) in portions to which the heat sinks 110 are attached, and the shape thereof is relatively arbitrary as long as the windbreak cover 111 covers an aerial wiring portion of the optical fiber 107 at a position lower than heat release fins of the heat sink 110.

By providing the windbreak cover 111 as just described, it can be prevented that the transmission line such as the optical fiber 107 which is aerially wired vibrates due to wind to cause fatigue and damage of an attachment portion. Further, by covering projections and depressions on the mounting board 102, the effect of improving the overall flow of the cooling air is produced and the effects of increasing system cooling efficiency and saving energy are also produced. Incidentally, components mounted inside the windbreak cover 111 sometimes require some heat release, and it is possible to cope with this case by designing in such a manner that an opening is provided in a portion of the windbreak cover 111 so that main forced cooling air does not directly blow against the transmission line.

### Eighth Embodiment

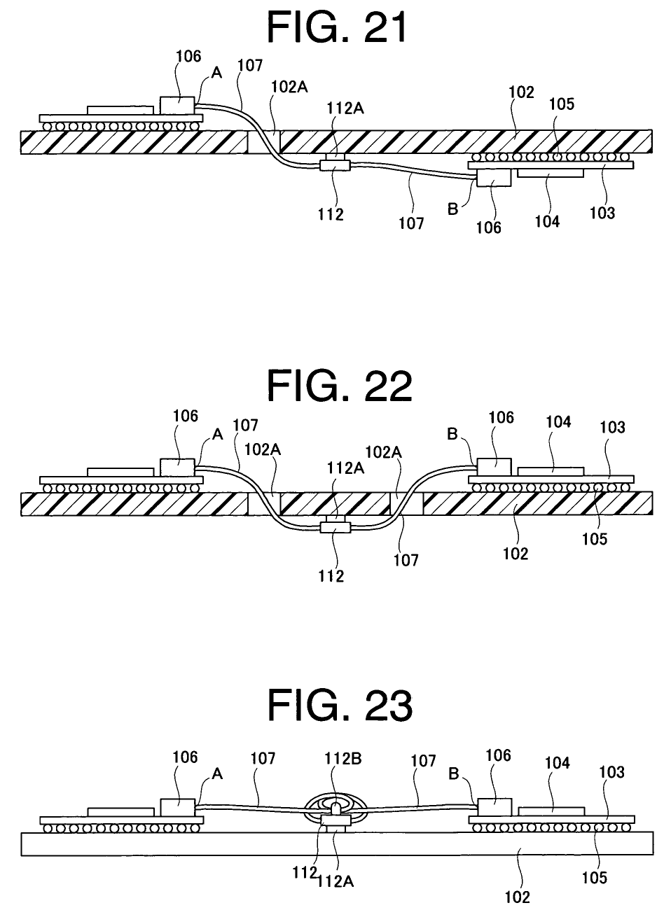

FIG. 21 is a structural view showing a transmission line package in an eighth embodiment of the present invention, and shows an example in which in place of fixing the deflection of the optical fiber by the hooks shown in FIG. 16, the optical fiber is drawn through an opening of the mounting board. In FIG. 21, numeral 102A denotes an opening of the mounting board, numeral 112 denotes a connecting unit (such as a connector, a splicer, or the like), numeral 112A denotes a mounting board fixture (for example, a double-sided adhesive tape) of the connecting unit, and the others are the same as those in the sixth embodiment.

As shown in FIG. 21, one LSI package substrate 103 and so on are mounted on the front surface side of the mounting board 102, and the other LSI package substrate 103 and so on are mounted on the rear surface side of the mounting board 102. The opening 102A through which to draw the optical fiber 107 is formed in the mounting board 102, and the optical fiber 107 is drawn out from the front surface side to the rear surface side of the mounting board 102 via the opening 102A. Incidentally, at least one or more openings 102A need to be formed in the mounting board 102, and plural openings may be formed.

The connecting unit 112 is situated between the first wiring point A and the second wiring point B, and placed on the rear surface side of the mounting board 102. In this embodiment, two optical fibers 107 are used and connected by the connecting unit 112.

This structure is applicable to a case where aerial wiring of the transmission line such as the optical fiber 107 is installed from the front surface side of the mounting board 102 to the rear surface side of the mounting board 102. Further, in the case of a structure in which the transmission line is attached, for example, a so-called pig tail type in which the transmission line is fixed to the interface module, it is required to provide a relay portion using the connecting unit 112 so that the opening 102A of the mounting board 102 is minimized. However, when the transmission line can be retrofitted to the interface module or when the opening 102A sufficient to draw the interface module through is provided, the connecting unit 112 is not necessarily required. By such a structure, a deflection portion is formed by itself in the transmission line, and the deflection caused by the wiring length error is accommodated by an S-shaped deflection portion in FIG. 20.

### Ninth Embodiment

FIG. 22 is a structural view showing a transmission line package in an ninth embodiment of the present invention, and shows an example in which in place of fixing the deflection of the optical fiber by the hooks shown in FIG. 16, the optical fiber is drawn through an opening of the mounting board. In FIG. 22, numeral 102A denotes an opening of the mounting board, numeral 112 denotes a connecting unit (such as a connector, a splicer, or the like), numeral 112A denotes amounting board fixture (for example, a double-sided adhesive tape) of the connecting unit, and the others are the same as those in the sixth embodiment.

As shown in FIG. 22, two openings 102A to draw the optical fiber 107 through are provided in the mounting board 102, and the optical fiber 107 is drawn out from the front surface side to the rear surface side of the mounting board 102 via the opening 102A and further drawn out again to the front surface side of the mounting board 102 via the opening 102A.

The connecting unit 112 is situated between the first wiring point A and the second wiring point B, and placed on the rear surface side of the mounting board 102. In this embodiment, two optical fibers 107 are used and connected by the connecting unit 112.

In this structure, in the case of a structure in which the transmission line is attached, for example, a so-called pig tail type in which the transmission line is fixed to the interface module, it is required to provide a relay portion using the connecting unit 112 so that the openings 102A of the mounting board 102 are minimized. However, when the transmission line can be retrofitted to the interface module or when the openings sufficient to draw the interface module through are provided, the connecting unit 112 is not necessarily required, and the hooks 108 need to be provided, instead. By such a structure, a deflection portion is formed by itself in the transmission line, and the deflection caused by the wiring length error is accommodated by an S-shaped deflection portion in FIG. 22.

### Tenth Embodiment

FIG. 23 is a structural view showing a transmission line package in a tenth embodiment of the present invention, and shows an example in which the deflection of the optical fiber shown in FIG. 16 is accommodated by a hook provided on a connecting unit. In FIG. 23, numeral 112 denotes a connecting unit (such as a connector, a splicer, or the like), numeral 112A denotes a mounting board fixture (for example, a double-sided adhesive tape) of the connecting unit, numeral 112B denotes a hook of the connecting unit, and the others are the same as those in the sixth embodiment.

As shown in FIG. 23, the connecting unit 112 is situated between the first wiring point A and the second wiring point B, and placed on the front surface side of the mounting board 102. In this embodiment, two optical fibers 107 are used and connected by the connecting unit 112. The hook 112B of the connecting unit 112 is to wind the extra optical fiber 107 there around. In the process of connecting the optical fiber 107, the optical fiber 107 is connected, leaving a sufficient extra length, and the extra length of the optical fiber 107 is wound around the hook 112B of the connecting unit 112.

This structure is applicable to, for example, a so-called pig tail type in which the transmission line such as the optical fiber 7 is fixed to the interface module.

### Eleventh Embodiment

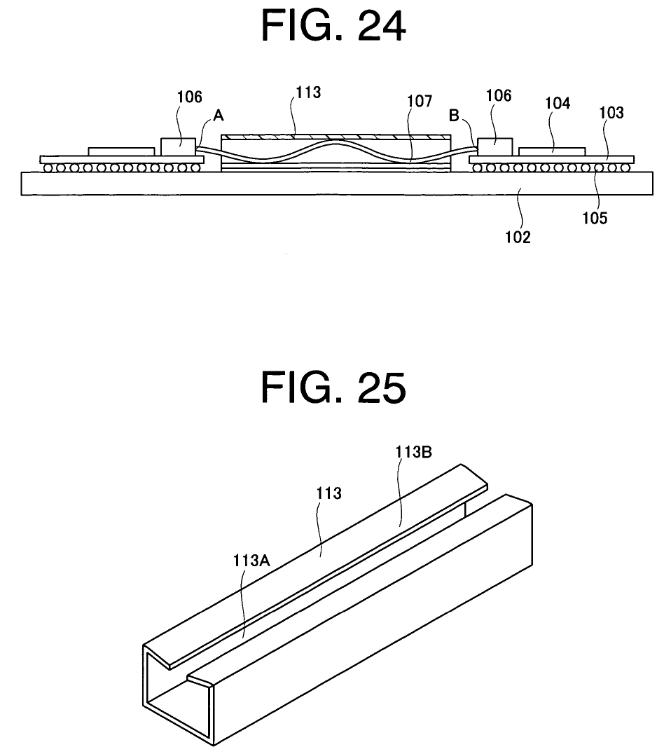

FIG. 24 is a structural view showing a transmission line package in an eleventh embodiment of the present invention, FIG. 25 is a perspective view showing a channel holder in the eleventh embodiment of the present invention, and both show an example in which the same effect is produced by housing the optical fiber in a channel holder instead of fixing the deflection of the optical fiber by the hooks in FIG. 16. In FIG. 24 and FIG. 25, numeral 113 denotes a channel holder, numeral 113A is a slit, numeral 113B denotes a claw portion, and the others are the same as those in the sixth embodiment.

As shown in FIG. 24, the optical fiber 107 is covered with the channel holder 113 which houses the optical fiber 107 at a predetermined height or lower. The channel holder 113 is formed by providing the slit 113A in one side surface of a four-sided pipe. Incidentally, the channel holder 113 may be formed by making a slit in a circular pipe. This case is easy to use especially when the transmission line is of a ribbon array type.

By housing the optical fiber 107 internally from the slit 113A, the deflection is automatically formed inside the channel holder 113 as shown in FIG. 24. In this case, there is an advantage that the transmission line automatically divides the deflection amount evenly by its own tension, and a case where the deflection amount is not divided evenly corresponds to either a case where the deflection amount is not so large or a case where the deflection is extremely large so that the wiring length error cannot be accommodated in the channel holder 113. In the case of the present invention, the length of the transmission line is set longer than the wiring length on the mounting board 102 by a range of 2% to 20% as described above, such an extreme case that the deflection cannot be accommodated in the channel holder 113 is not included.

The channel holder 113 may be a molded article of low-cost resin such as polyethylene resin or recycled resin of PET bottles, and if being provided with a slit (opening) to introduce the transmission line, the channel holder 113 can house the transmission line after the transmission line is placed. Further, in the case of a simple four-sided pipe, the transmission line may protrude from the slit by tension, but by providing the claw portions 113B to hold the transmission line inside the opening of the channel as shown in FIG. 25, the introduction of the transmission line is facilitated, and the transmission line is easily prevented from protruding. Incidentally, the claw portion 113B can be formed by bending a slat portion of the slit 113A toward the inside of the channel cover 113.

In this structure, the deflection height can be limited in advance, and the necessary number of inflection points (number of times of bulking) of the deflection is determined by the transmission line itself by the transmission line such as the optical fiber 107 going forward in the channel holder 113. Moreover, this structure has the effect of preventing the aerially wired transmission line from being vibrated and damaged by the forced cooling air from the cooling fan, and if the channel holder 113 is installed at a position lower than the heat sink, a reduction in cooling efficiency seldom occurs.

### Twelfth Embodiment

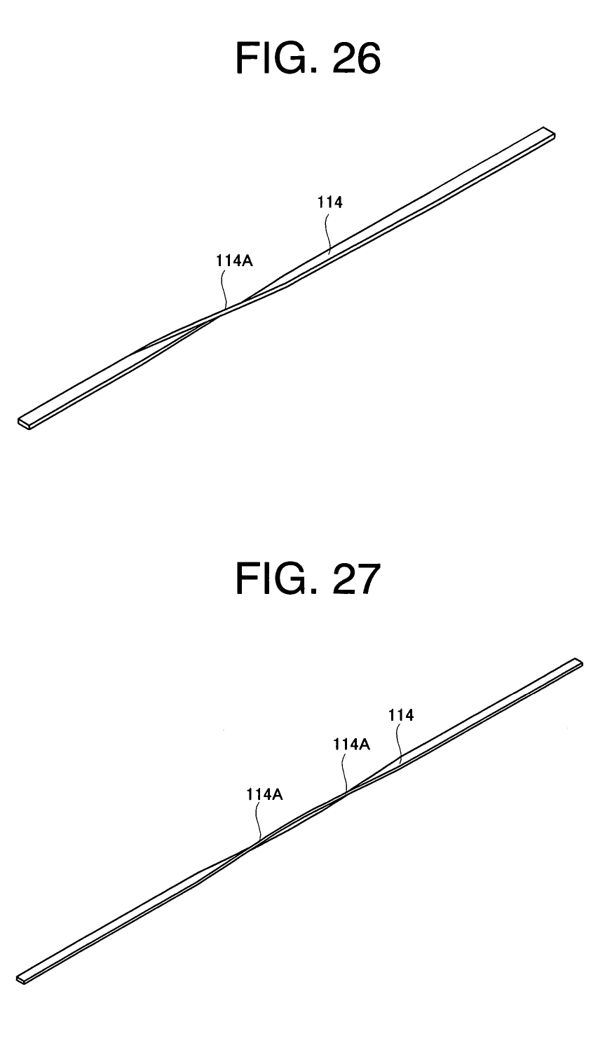

FIG. 26 and FIG. 27 are perspective views showing a ribbon optical fiber in a twelfth embodiment of the present invention, and show an example of a case where the transmission line is of a ribbon array type (such as a ribbon optical fiber). This embodiment shows an example in which in place of fixing the deflection of the optical fiber by the hooks shown in FIG. 16, a twisted portion is provided in the middle of the ribbon optical fiber to accommodate the deflection caused by the wiring length error. In FIG. 26 and FIG. 27, numeral 114 denotes a ribbon optical fiber, numeral 114A denotes a twisted portion provided in the ribbon optical fiber, and the others are the same as those in the sixth embodiment. An end portion of the ribbon optical fiber 114 is attached to the interface module 106 as in the sixth embodiment, although not shown.

As the ribbon optical fiber 114, for example, 12 quartz fiber core wires each with a clad outer diameter of 125 μm which are arranged in a line at a pitch of 250 μm can be used. In this ribbon optical fiber 114, at least one or more twisted portions 114A are formed between the first wiring point A and the second wiring point B. In this embodiment, the twisted portion 114A is formed by rotating (twisting) the ribbon optical fiber 114 by 180° with its longitudinal direction as an axis as shown in FIG. 26. Consequently, although, when the twisted portion 114A is not provided, a wiring length error of approximately several millimeters causes a centimeter-level deflection, by providing the twisted portion 114A, in a range of a relatively small wiring length error, for example, a wiring length error of approximately 5 mm when the wiring length is 20 cm, the effect of lateral dispersion of the deflection is added, so that the deflection does not become so high.

Further, in the example shown in FIG. 26, the ribbon optical fiber 114 is twisted by 180°, so that the arrangement on a plane is reversed, and therefore in the case of unidirectional wiring, the need for inversely rearrange channel arrangement of two LSI packages arises (so that sending and receiving terminals do not engage with each other). In contrast, in the case of bidirectional wiring, there is a advantage that channel matching is achieved without changing arrangement. In either case, to obtain the same wiring form as the simple ribbon optical fiber wiring, a 360-degree twist is desirable instead of a 180-degree twist. Furthermore, if, as another method in this case, the twisted portion 114A is reversed alternately, that is, a right-handed twist and a left-handed twist are alternately repeated the same number of times as shown in FIG. 27, the same effect is obtained.

### Thirteenth Embodiment

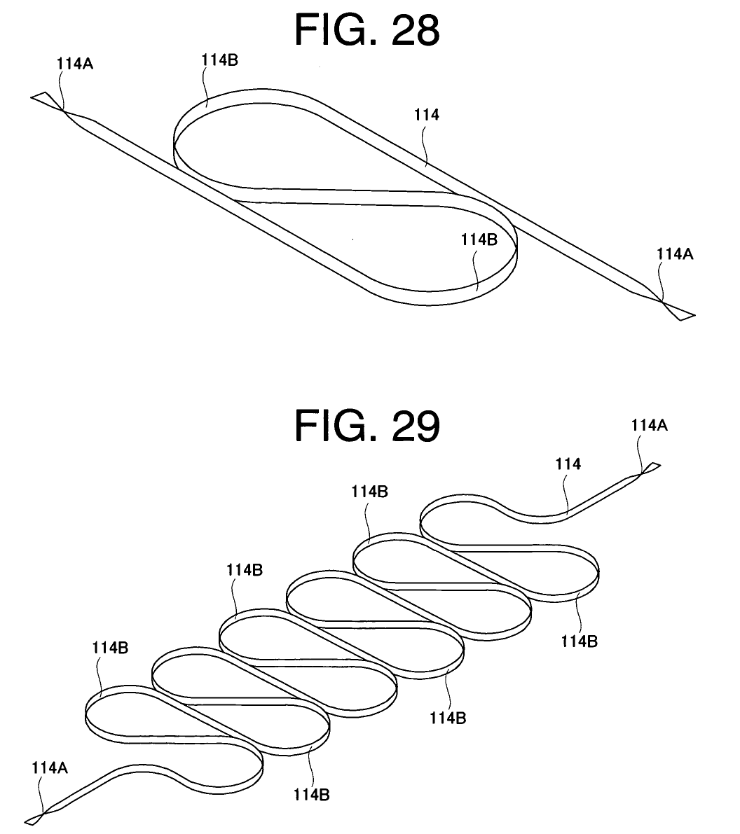

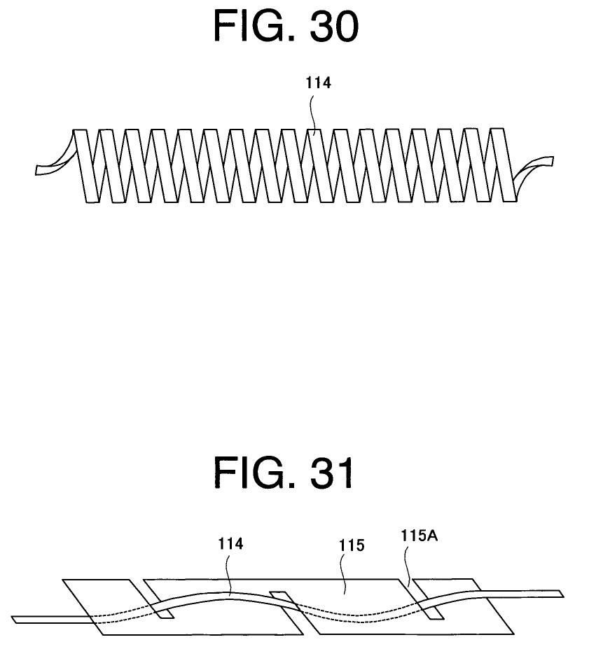

FIG. 28 and FIG. 29 are perspective views showing a ribbon optical fiber in a thirteenth embodiment of the present invention, FIG. 30 is a side view showing the ribbon optical fiber in the thirteenth embodiment of the present invention, and both show an example of a case where the transmission line is of a ribbon array type (such as a ribbon optical fiber). This embodiment shows an example in which in place of fixing the deflection of the optical fiber by the hooks shown in FIG. 16, by forming a deflection shape by folding back the middle of the ribbon optical fiber in advance, the wiring length error is accommodated by a spring effect of a curved portion (folded portion) of the ribbon optical fiber. In FIG. 28 to FIG. 30, numeral 114 denotes a ribbon optical fiber, numeral 114A denotes a twisted portion provided in the ribbon optical fiber, numeral 114B denotes a curved portion provided in the ribbon optical fiber, and the others are the same as those in the sixth embodiment.

As the ribbon optical fiber 114, for example, 12 quartz fiber core wires each with a clad outer diameter of 125 μm which are arranged in a line at a pitch of 250 μm can be used. In this ribbon optical fiber 114, at least one or more curved portions 114B are formed between the first wiring point A and the second wiring point B and in a direction orthogonal to an array arrangement direction. In this embodiment, two curved portions 114B with a radius of curvature of 15 mm are provided in a plane direction of the ribbon optical fiber 114 as shown in FIG. 28.

Such curved portions 114B can be formed, for example, by winding the ribbon optical fiber 114 around two guide bars and gradually cooling it with the guide bars after heating it to 150° C. so as to hold its shape. Thereby, the wiring length error is accommodated by the spring effect of the curved portions 114B of the ribbon optical fiber, and a phenomenon in which the transmission line such as the ribbon optical fiber 114 deflects (rises) onto the mounting board 102 due to the wiring length error is prevented.

Incidentally, as shown in FIG. 28, the arrangement direction of both end portions of the ribbon optical fiber 114 is a lateral direction. Namely, the twisted portions 114A which are formed by rotating (twisting) the ribbon optical fiber 114 by 90° with its longitudinal direction as an axis are formed at the end portions of the ribbon optical fiber 114. As a result, the ribbon optical fiber 114 can easily connect with the interface module. Moreover, it is also possible to stand the folded ribbon optical fiber in FIG. 28 and use the end portions in a horizontal position. Further, by describing many curves as shown in FIG. 29 instead of describing two curves (one turn) as shown in FIG. 28, the ribbon optical fiber may have a so-called bellows shape. Furthermore, the ribbon optical fiber 114 may have a coil shape as shown in FIG. 30. The coil-shaped ribbon optical fiber 114 can be formed by winding the ribbon optical fiber 114 around one guide bar so as to involve gentle twists and gradually cooling it with the guide bar after heating it to 150° C. so as to hold its shape. Moreover, instead of a planar shape as shown in FIG. 29, the bellows may have a combined shape of a folded coil shape involving twists and the bellows in FIG. 29.

### Fourteenth Embodiment

FIG. 31 is a perspective view showing a ribbon optical fiber and a holding plate in a fourteenth embodiment of the present invention, and shows an example of a case where the transmission line is of a ribbon array type (such as a ribbon optical fiber). This embodiment shows an example in which by passing the ribbon optical fiber through the holding plate in such a manner that the holding plate is sewed in place of fixing the deflection of the optical fiber by the hooks shown in FIG. 16, the wiring length error is accommodated. In FIG. 31, numeral 114 denotes a ribbon optical fiber, numeral 115 denotes a holding plate, numeral 115A is an opening provided in the holding plate, and the others are the same as those in the sixth embodiment.

As the ribbon optical fiber 114, for example, 12 quartz fiber core wires each with a clad outer diameter of 125 μm which are arranged in a line at a pitch of 250 μm can be used. The holding plate 115 is placed between the first wiring point A and the second wiring point B, and in the holding plate 115, plural openings are formed at predetermined intervals in a direction from the first wiring point A to the second wiring point B. The ribbon optical fiber 114 is drawn through the openings 115A in such a manner that the holding plate 115 is sewed. By this structure, the deflection caused by the wiring length error is accommodated by a deflection portion in FIG. 31.

As described in detail above, according to the sixth embodiment to the fourteenth embodiment, the extremely large deflection of the transmission line on the mounting board is eliminated, and the problem that the transmission line becomes shorter than the predetermined length and is damaged, is eliminated, whereby even if the transmission line between the high-speed LSI chips is wired aerially, the high-yield and high-reliability transmission line package can be realized, which greatly contributes to the advancement of information communication equipment and so on. Further, by properly processing the extra length, it is possible to reduce the application of stress caused by the deflection or twist of the transmission line to connection portions between the optical interface and the interposer or the socket, which makes the pressing mechanism or the like to cope with the stress unnecessary, thereby enabling further reduction in size.

It should be noted that the present invention is not limited to the above-described embodiments. For example, the above-described embodiments make a description with a central focus on the optical fiber, but can be embodied using the small-diameter coaxial line or an array thereof as described above. Moreover, the materials, shapes, arrangements, and so on shown in the examples are only one example, and the present invention can be embodied by combining the respective examples. Additionally, the present invention can be embodied in various modified forms without departing from the spirit of the present invention.

What is claimed is:

1. An LSI package with an interface module, comprising:
an interposer, on which a signal processing LSI is mounted, having a mounting board connection electrical terminal; and
an interface module having a transmission line to wire a high-speed signal to an exterior,
wherein said interposer and said interface module have at least either loop electrodes or plate electrodes, respectively, and said interposer and said interface module are electrically connected by inductive coupling, electrostatic coupling, or combined coupling of these two couplings by at least either the loop electrodes or the plate electrodes.

2. An LSI package with an interface module, comprising:
an interposer, on which a signal processing LSI is mounted, having a mounting board connection electrical terminal;
an interface module having a transmission line to wire a high-speed signal to an exterior and;
an electrical connector mounted on at least either said interposer or said interface module; and
a flexible electrical wire whose at least one end portion is connected to said electrical connector,
wherein said interposer and said interface module have electrical connection terminals which are electrically connected, respectively, and the electrical connection terminals are electrically connected by said flexible electrical wire.

3. An LSI package with an interface module, comprising:
an interposer, on which a signal processing LSI is mounted, having a high-speed signal electrical terminal and a socket connection terminal pin;
an interface module having a transmission line to wire a high-speed signal to an exterior, a high-speed signal electrical terminal, and a socket connection terminal pin;
a high-speed signal wire electrically connecting the high-speed signal electrical terminal of said interposer and the high-speed signal electrical terminal of said interface module to each other; and
a socket having jacks fittable with the socket connection terminal pin of said interposer and the socket connection terminal pin of said interface module,
wherein the high-speed signal electrical terminal of said interposer and the high-speed signal electrical terminal of said interface module come into mechanical contact with said high-speed signal wire by pressing force due to deflections of the high-speed signal electrical terminals and get electrically connected to each other, and the mechanical contact is held by fitting the socket connection terminal pin of said interposer and the socket connection terminal pin of said interface module into the jacks, respectively.

4. An LSI package with an interface module, comprising:
an interposer, on which a signal processing LSI is mounted, having a mounting board connection electrical terminal; and
an interface module having an optical fiber to wire a high-speed signal to an exterior,
wherein said interposer and said interface module have electrical connection terminals which are electrically connected, respectively, and the electrical connection terminals are connected by a solder having a melting point lower than a board mounting solder.

5. A transmission line package, comprising:
a mounting board;
a transmission line aerially wired from a first wiring point on said mounting board to a second wiring point on said mounting board and longer than a shortest wiring length from the first wiring point to the second wiring point by a range not less than 2% nor more than 20% of the shortest wiring length; and
a hook which pulls said transmission line toward said mounting board at a height equal to or lower than a straight-line wiring height from the first wiring point to the second wiring point or a fixing member which fixes said transmission line to said mounting board.

6. The transmission line package as set forth in claim 5, further comprising
a windbreak cover provided in a region from the first wiring point to the second firing point and having an opening to release heat.

7. The transmission line package as set forth in claim 5,
wherein said fixing member is a channel holder which covers said transmission line and houses said transmission line at a predetermined height or lower.

8. A transmission line package, comprising:
a mounting board; and
a ribbon optical transmission line aerially wired from a first wiring point on said mounting board to a second wiring point on said mounting board, arranged in array long sideways, and having a twisted portion or a curved portion formed between the first wiring point and the second wiring point.

9. An LSI package with an interface module, comprising:
a signal processing LSI;
an interposer, on which said signal processing LSI is mounted, having a mounting board connection electrical terminal; and
an interface module having a ribbon optical transmission line composed of an optical waveguide body array to wire a high-speed signal to an exterior,
wherein said interposer and said interface module have electrical connection terminals which are electrically connected by mechanical contact, and
wherein the ribbon optical transmission line has a twisted portion or a curved portion.

10. A ribbon optical transmission line which is linearly arranged in array in a direction orthogonal to an optical transmission direction, comprising
a twisted portion, or a curved portion in a direction orthogonal to the direction of the array arrangement in a middle of said ribbon optical transmission line.
